(19) United States
(12) Patent Application Publication
(10) Pub. No.: US 2026/0366159 A1
(43) Pub. Date: Nov. 19, 2026

(54) OVERLAP STRUCTURE FOR USE IN SEMICONDUCTOR PROCESSING CHAMBER

(71) Applicant: Applied Materials, Inc., Santa Clara, CA (US)

(72) Inventors: Zhepeng CONG, San Jose, CA (US); Errol Antonio C. SANCHEZ, Tracy, CA (US); Paul BRILLHART, Pleasanton, CA (US); Benjamin Ean THAM, Elk Grove, CA (US); Abraham PALATY, San Jose, CA (US)

(21) Appl. No.: 19/677,621

(22) Filed: May 14, 2026

Related U.S. Application Data
(60) Provisional application No. 63/808,039, filed on May 19, 2025.

(51) Int. Cl. C23C 16/458; C23C 16/44; C23C 16/46

(52) U.S. Cl. CPC C23C 16/4585; C23C 16/4408; C23C 16/4412; C23C 16/46

(57) ABSTRACT

Embodiments of the present disclosure generally relate to an overlap structure configured to reduce migration of process gas species toward a backside of a substrate support in a semiconductor processing chamber, and to improve thermal uniformity near the substrate support. In one or more embodiments, a processing chamber applicable for use in semiconductor manufacturing includes a chamber body at least partially defining a processing volume. A substrate support is disposed in the processing volume. A pre-heat ring is disposed at least partially outwardly of the substrate support. An overlap structure is disposed below the substrate support. At least a portion of the overlap structure extends below the pre-heat ring.

### CROSS-REFERENCE TO RELATED APPLICATIONS

This application claims priority to United States Provisional Patent Application 63/808,039, filed on May 19, 2025, the contents of which are incorporated herein by reference.

### BACKGROUND

### Field

Embodiments of the present disclosure generally relate to an overlap structure configured to reduce migration of process gas species toward a backside of a substrate support in a semiconductor processing chamber, and to improve thermal uniformity near the substrate support.

### Description of the Related Art

Epitaxial processing chambers are used to grow crystalline layers on semiconductor wafers through chemical vapor deposition (CVD). These chambers typically include a substrate support, which holds the wafer in place, and a preheat ring surrounding the support. The preheat ring helps maintain thermal uniformity across the wafer during processing by minimizing edge-related temperature variations. Temperature and gas flow control are essential to ensure high-quality epitaxial layer growth with minimal defects.

A gap is typically present between the preheat ring and the substrate support to allow the substrate support to rotate during processing. However, during processing, gases introduced into the chamber to react and deposit material on the wafer surface can flow over both the substrate support and the preheat ring, and may inadvertently enter this gap. When this occurs, process gas species can migrate toward a backside of the substrate support and/or into the volume below the substrate support, including by diffusion driven by concentration differences between regions of the processing chamber. Such migration can result in unwanted backside deposition, changes in local chamber conditions, or increased maintenance requirements. Such backside exposure or unwanted deposition can degrade system performance, affect wafer processing conditions, and require more frequent maintenance.

Therefore, there is a need in the art for improved chamber components that reduce migration of process gas species toward a backside of a substrate support while maintaining pressure equalization between regions of the processing chamber.

### SUMMARY

Embodiments of the present disclosure generally relate to an overlap structure configured to reduce migration of process gas species toward a backside of a substrate support in a semiconductor processing chamber, and to improve thermal uniformity near the substrate support.

In one or more embodiments, a processing chamber applicable for use in semiconductor manufacturing includes a chamber body at least partially defining a processing volume. A substrate support is disposed in the processing volume. A pre-heat ring is disposed at least partially outwardly of the substrate support. An overlap structure is disposed below the substrate support. At least a portion of the overlap structure extends below the pre-heat ring.

In one or more embodiments, an overlap structure for use in a semiconductor processing chamber includes an inner portion and an outer portion disposed outwardly of the inner portion. The inner portion and the outer portion are parallel to one another. A protrusion feature is disposed between the inner portion and the outer portion. The protrusion feature is perpendicular to the inner portion and the outer portion. One or more openings extend through the inner portion of the overlap structure.

In one or more embodiments, a processing chamber applicable for use in semiconductor manufacturing includes a chamber body and a plate. The chamber body and the plate at least partially define a processing volume. One or more heat sources are configured to heat the processing volume. A substrate support is disposed in the processing volume. A pre-heat ring is disposed at least partially outwardly of the substrate support. An overlap structure is disposed below the substrate support. At least a portion of the overlap structure extends below the pre-heat ring. The overlap structure includes an inner portion, an outer portion, and a protrusion feature disposed between the inner portion and the outer portion. The protrusion feature is perpendicular to the inner portion and the outer portion. A first gap is defined by a distance between the protrusion feature of the overlap structure and a lower surface of the substrate support. A second gap is defined by a distance between an upper surface of the outer portion of the overlap structure and the lower surface of the substrate support. A third gap is defined by a distance between an upper surface of the inner portion of the overlap structure and the lower surface of the substrate support. A fourth gap is defined by a distance between the pre-heat ring and the substrate support.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 is a schematic side cross-sectional view of a processing chamber, according to one or more embodiments.

FIG. 2 is a schematic cross sectional view of an overlap structure disposed below a substrate support, according to one or more embodiments.

FIG. 3A is a schematic cross sectional view of an overlap structure, according to one or more embodiments.

FIG. 3B is a schematic isometric view of an overlap structure, according to one or more embodiments.

FIGS. 4A-4G are schematic cross sectional views of a portion of an overlap structure, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to an overlap structure configured to reduce migration of process gas species toward a backside of a substrate support in a semiconductor processing chamber, and to improve thermal uniformity near the substrate support.

The disclosure contemplates that terms such as “couples,” “coupling,” “couple,” and “coupled” may include but are not limited to embedding, bonding, welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

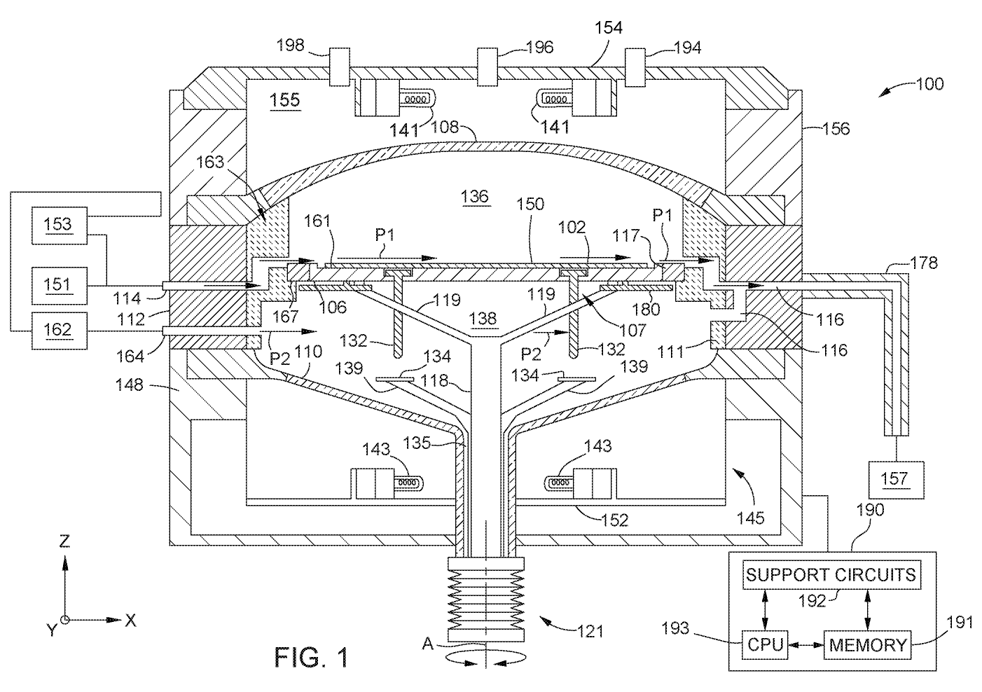

FIG. 1 is a schematic side cross-sectional view of a processing chamber 100, according to one or more embodiments. The processing chamber 100 is a deposition chamber. In one or more embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102. The processing chamber 100 is shown in a processing condition in FIG. 1.

The processing chamber 100 includes an upper body 156, a lower body 148 disposed below the upper body 156, and a flow module 112 disposed between the upper body 156 and the lower body 148. The upper body 156, the flow module 112, and the lower body 148 form a chamber body. Disposed within the chamber body is a substrate support 106, an upper plate 108 (such as an upper window, for example an upper dome), a lower plate 110 (such as a lower window, for example a lower dome), a plurality of upper heat sources 141, and a plurality of lower heat sources 143. In one or more embodiments, the upper heat sources 141 include upper lamps and the lower heat sources 143 include lower lamps. The present disclosure contemplates that other heat sources may be used (in addition to or in place of the lamps) for the various heat sources described herein. For example, resistive heaters, light emitting diodes (LEDs), and/or lasers may be used for the various heat sources described herein.

The substrate support 106 is disposed between the upper plate 108 and the lower plate 110. The substrate support 106 supports the substrate 102. In one or more embodiments, the substrate support 106 includes a susceptor. Other substrate supports (including, for example, a substrate carrier and/or one or more ring segment(s) that support one or more outer regions of the substrate 102) are contemplated by the present disclosure. The plurality of upper heat sources 141 are disposed between the upper plate and a lid 154. The plurality of upper heat sources 141 form a portion of an upper heat source module 155.

The plurality of lower heat sources 143 are disposed between the lower plate 110 and a floor 152. The plurality of lower heat sources 143 form a portion of a lower heat source module 145. The upper plate 108 is an upper dome and/or is formed of an energy transmissive material, such as quartz. The lower plate 110 is a lower dome and/or is formed of an energy transmissive material, such as quartz.

A processing volume 136 and a purge volume 138 are formed between the upper plate 108 and the lower plate 110. The processing volume 136 and the purge volume 138 are part of an internal volume defined at least partially by the upper plate 108, the lower plate 110, and one or more liners 111, 163 of the chamber body. The processing volume 136 has the substrate support 106 disposed therein. The substrate 102 is disposed on the substrate support 106. The substrate support 106 is attached to a shaft 118. In one or more embodiments, the substrate support 106 is connected to the shaft 118 through one or more arms 119 connected to the shaft 118. The shaft 118 is connected to a motion assembly 121. The motion assembly 121 includes one or more actuators and/or adjustment devices that provide movement and/or adjustment for the shaft 118 and/or the substrate support 106 within the processing volume 136.

The substrate support 106 may include lift pin holes 107 disposed therein. The lift pin holes 107 are each sized to accommodate a lift pin 132 for lifting of the substrate 102 from the substrate support 106 before or after a deposition process is performed. The lift pins 132 may rest on lift pin stops 134 when the substrate support 106 is lowered from a process position to a transfer position. The lift pin stops 134 can include a plurality of arms 139 that attach to a shaft 135.

The flow module 112 includes one or more gas inlets 114 (e.g., a plurality of gas inlets), one or more purge gas inlets 164 (e.g., a plurality of purge gas inlets), and one or more gas exhaust outlets 116. The one or more gas inlets 114 and the one or more purge gas inlets 164 are disposed on the opposite side of the flow module 112 from the one or more gas exhaust outlets 116.

A pre-heat ring 117 is disposed below the one or more gas inlets 114 and the one or more gas exhaust outlets 116. The pre-heat ring 117 is disposed above the one or more purge gas inlets 164. The pre-heat ring 117 is disposed at least partially outwardly of the substrate support 106. The one or more liners 111, 163 are disposed on an inner surface of the flow module 112 and protect the flow module 112 from reactive gases used during deposition operations and/or cleaning operations. The gas inlet(s) 114 and the purge gas inlet(s) 164 are each positioned to flow a respective one or more process gases P1 and one or more purge gases P2 parallel to the top surface 150 of a substrate 102 disposed within the processing volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. The one or more process gases P1 supplied using the one or more process gas sources 151 can include one or more reactive gases (such as one or more of silicon (Si), phosphorus (P), and/or germanium (Ge) containing gases) and/or one or more carrier gases (such as one or more of nitrogen (N₂) and/or hydrogen (H₂) containing gases). The one or more purge gases P2 supplied using the one or more purge gas sources 162 can include one or more inert gases (such as one or more of argon (Ar), helium (He), and/or nitrogen (N₂) containing gases). One or more cleaning gases supplied using the one or more cleaning gas sources 153 can include one or more of hydrogen (H) and/or chlorine (Cl) containing gases. In one or more embodiments, the one or more process gases P1 include one or more silicon-containing gases (such as silane and/or dichlorosilane) and/or phospine (PH₃), and the one or more cleaning gases include hydrochloric acid (HCl).

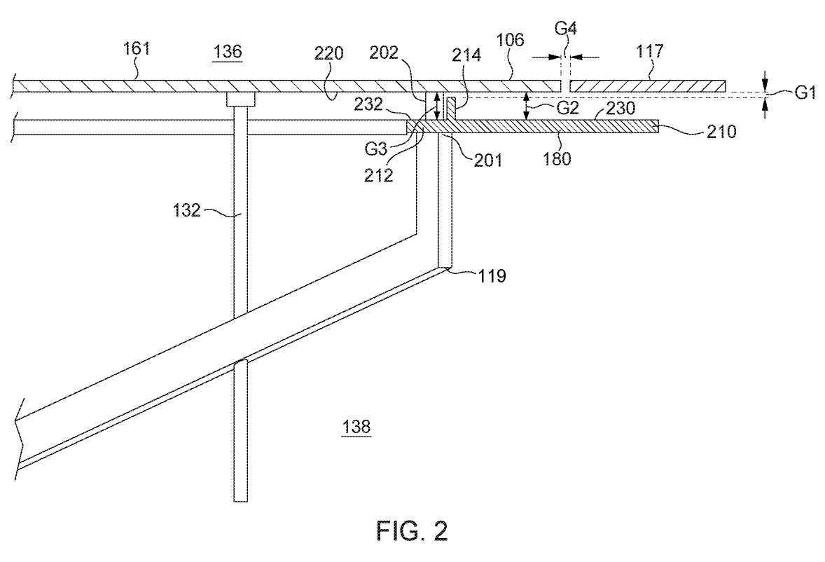

In one or more embodiments, an overlap structure 180 is disposed below the substrate support 106. The overlap structure 180 is described in greater detail in FIGS. 2-4. The overlap structure 180 helps control migration of the one or more process gases P1 toward a backside of the substrate support 106 and into the purge volume 138. In one or more embodiments, the overlap structure 180 increases a path length between the processing volume 136 and the backside of the substrate support 106, thereby reducing diffusion of process gas species toward the backside of the substrate support 106. The overlap structure 180 also permits pressure equalization between the purge volume 138 and the processing volume 136 such that the overlap structure 180 remains tolerant or stable under dynamic pressure differentials between the purge volume 138 and the processing volume 136.

The one or more gas exhaust outlets 116 are further connected to or include an exhaust system 178. The exhaust system 178 fluidly connects the one or more gas exhaust outlets 116 and the exhaust pump 157. The exhaust system 178 can assist in the controlled deposition of a layer on the substrate 102. The exhaust system 178 is disposed on an opposite side of the processing chamber 100 relative to the flow module 112.

The processing chamber 100 includes the one or more liners 111, 163 (e.g., a lower liner 111 and an upper liner 163). The lower liner 111 and the upper liner 163 are disposed inwardly of a sidewall (e.g., the flow module 112 and/or the upper body 156) of the chamber body. The flow module 112 (which can be at least part of the sidewall of the processing chamber 100) includes the one or more gas inlets 114 in fluid communication with the processing volume 136. The one or more gas inlets 114 are in fluid communication with one or more flow gaps between the upper liner 163 and a lower liner 111. The one or more of the liners 111, 163 include one or more ledges 167 supporting the pre-heat ring 117.

The present disclosure also contemplates that the one or more purge gases P2 can be supplied to the purge volume 138 (through the one or more purge gas inlets 164) during the deposition operation, and exhausted from the purge volume 138. The one or more purge gases P2 flow simultaneously with the flowing of the one or more process gases P1. The one or more process gases P1 are exhausted through gaps between the upper liner 163 and the lower liner 111, and through the one or more gas exhaust outlets 116. The one or more purge gases P2 can be exhausted through one or more outlet openings, and through the same one or more gas exhaust outlets 116 as the one or more process gases P1. The present disclosure contemplates that that the one or more purge gases P2 can be separately exhausted through one or more second gas exhaust outlets that are separate from the one or more gas exhaust outlets 116.

During a cleaning operation, one or more cleaning gases flow through the one or more gas inlets 114, through the one or more gaps (between the upper liner 163 and the lower liner 111), and into the processing volume 136.

The processing system includes one or more sensors 194, 196, 198 (e.g., temperature sensors) configured to measure parameter(s) (e.g., temperature(s)) within the processing chamber 100. In one or more embodiments, the one or more sensors 194, 196, 198 include a central sensor 196 and one or more outer sensors 194, 198. A controller 190 (described below) can control the one or more sensors 194, 196, 198 and/or one or more heat sources 141, 143, and can conduct method(s) of adjusting uniformity of substrate processing using at least one of the one or more sensors 194, 196, 198 and/or one or more heat sources 141, 143. In one or more embodiments, one or more sensors 194, 196, 198 each include a pyrometer, such as a pyrometer that includes a silicon sensor. In one or more embodiments, each sensor 194, 196, 198 is an optical sensor, such as an optical pyrometer. The present disclosure contemplates that sensors other than pyrometers may be used, and/or one or more of the sensors 194, 196, 198 can measure properties other than temperature.

In one or more embodiments, the sensors 194, 196, 198 include one or more upper sensors 194, 196, 198 disposed above the substrate 102 and adjacent the lid 154. Each sensor 194, 196, 198, can be a single-wavelength sensor device or a multi-wavelength (such as dual-wavelength) sensor device. In one or more embodiments, the system including the process chamber 100 includes any one, any two, or any three of the four illustrated sensors 194, 196, 198. In one or more embodiments, the process chamber 100 includes one or more additional sensors, in addition to the sensors 194, 196, 198. In one or more embodiments, the process chamber 100 may include sensors disposed at different locations and/or with different orientations than the illustrated sensors 194, 196, 198.

As shown, the controller 190 is in communication with the processing chamber 100 and is used to control processes and methods, such as the operations of the methods described herein.

The controller 190 is configured to receive data or input as sensor readings from sensor(s) (such as one or more of the sensors 194, 196, 198). The sensors can include, for example: sensors that monitor growth of layer(s) on the substrate 102; and/or sensors that monitor temperatures of the substrate 102, the substrate support 106, and/or the liners 111, 163. The controller 190 is equipped with or in communication with a system model of the processing chamber 100. The system model includes a heating model, a temperature uniformity model, a film uniformity model, a film deposition rate model, a coating model, a rotational position model, and/or a gas flow model. The system model is a program configured to estimate parameters (such as a signal profile (e.g., a temperature profile) of the substrate 102 and/or the substrate support 106, a gas flow rate, a gas pressure, a rotational position of component(s), a heating profile, a coating condition, and/or a cleaning condition) within the processing chamber 100 throughout a deposition operation and/or a cleaning operation. The controller 190 is further configured to store readings and calculations. The readings and calculations include previous sensor readings, such as any previous sensor readings within the processing chamber 100. The readings and calculations further include the stored calculated values from after the sensor readings are measured by the controller 190 and run through the system model. Therefore, the controller 190 is configured to both retrieve stored readings and calculations as well as save readings and calculations for future use. Maintaining previous readings and calculations enables the controller 190 to adjust the system model over time to reflect a more accurate version of the processing chamber 100.

The controller 190 can monitor heating, generate a signal profile (e.g., a temperature profile), identify set(s) of one or more heat sources, adjust a heating profile, adjusting heating power(s), estimate an optimized parameter (such as the target temperature), adjust the one or more sensors 194, 196, 198 generate an alert on a display, halt a deposition operation, initiate a chamber downtime period, delay a subsequent iteration of the deposition operation, initiate a cleaning operation, halt the cleaning operation, and/or otherwise adjust the process recipe.

The controller 190 includes a central processing unit (CPU) 193 (e.g., a processor), a memory 191 containing instructions, and support circuits 192 for the CPU 193. The controller 190 controls various items directly, or via other computers and/or controllers. In one or more embodiments, the controller 190 is communicatively coupled to dedicated controllers, and the controller 190 functions as a central controller.

FIG. 2 is a schematic cross sectional view of the overlap structure 180 disposed below the substrate support 106, according to one or more embodiments. In one or more embodiments, the one or more arms 119 are disposed below the substrate support 106. Each of the one or more arms 119 includes a support pin 202. The support pin 202 is disposed between a support surface 201 of each of the one or more arms 119 and a lower surface 220 of the substrate support 106. In one or more embodiments, the support pin 202 is formed of a silicon carbide material. In one or more embodiments, the overlap structure 180 is disposed between an arm tip region of the one or more arms 119 and the lower surface 220 of the substrate support 106. The overlap structure 180 can provide a more uniform thermal environment between the support surface 201 and the lower surface 220 of the substrate support 106, thereby reducing localized thermal non-uniformities or hot spots at or near locations where the support pins 202 contact the substrate support 106. The overlap structure 180 is disposed between the support surface 201 of each of the one or more arms 119 and a lower surface 220 of the substrate support 106. Each support pin 202 is disposed through one or more openings extending through the overlap structure 180. In one or more embodiments, the overlap structure 180 includes an outer portion 210, an inner portion 212 and a protrusion feature 214. In one or more embodiments, the one or more openings extend through the outer portion 210 of the overlap structure 180. The protrusion feature 214 can either be on the outer or inner side of the support pin 202 (ie, closer to or farther from the outer diameter of the substrate support 106). In one or more embodiments, the overlap structure 180 is supported by the shaft 118.

In one or more embodiments, the overlap structure 180 is an annular ring. In one or more embodiments, the overlap structure 180 is a plate. In one or more embodiments, the overlap structure is a circular plate. The circular plate does not include a central opening. In one or more embodiments, the overlap structure 180 and the substrate support 106 are axially aligned with one another so that the overlap structure 180 and the substrate support 106 share the same central axis. In one or more embodiments, the outer portion 210 and the inner portion 212 are parallel to the substrate support 106. In one or more embodiments, the inner portion 212 includes a central opening defining an inner dimension. The protrusion feature 214 is between the inner portion 212 and the outer portion 210. The protrusion feature 214 extends towards the lower surface 220 of the substrate support 106. In one or more embodiments the protrusion feature 214 is perpendicular to the substrate support 106.

A first gap G1 is defined by the distance between the protrusion feature 214 and the lower surface 220 of the substrate support 106. The first gap G1 reduces direct thermal conduction between the substrate support 106 and the overlap structure 180. A second gap G2 is defined by the distance between an upper surface 230 of the outer portion 210 and the lower surface 220 of the substrate support 106. A third gap G3 is defined by the distance between an upper surface 232 of the inner portion 212 and the lower surface 220 of the substrate support 106. The first gap G1 is less than the second gap G2 and the third gap G3. In one or more embodiments, the second gap G2 and the third gap G3 are equivalent. In one or more embodiments, the second gap G2 and the third gap G3 are different from one another. The second gap G2 is from about 3mm to about 30mm.

A fourth gap G4 separates the pre-heat ring 117 and the substrate support 106. The outer portion 210 of the overlap structure 180 extends past the fourth gap G4 so that at least a portion of the outer portion 210 is disposed under the pre-heat ring 117. During a processing operation, one or more process gases flow over the top surface 161 of the substrate support 106. The one or more process gases may flow through the fourth gap G4 into the purge volume 138. The outer portion 210 of the overlap structure 180 extends the migration path from the processing volume 136 to the backside of the substrate support 106 and/or the purge volume 138. The extended migration path reduces diffusion of process gas species toward the backside of the substrate support 106, including diffusion driven by a concentration difference between the processing volume 136 and the purge volume 138. In one or more embodiments, the pressure within the purge volume 138 and/or processing volume 136 is rapidly increased or decreased. The second gap G2 allows pressure equalization between the purge volume 138 and the processing volume 136. When the pressure within either the purge volume 138 or the processing volume 136 changes, the second gap G2 enables one or more gases to flow between the purge volume 138 and the processing volume 136, which prevents a significant pressure differential from developing between the purge volume 138 and the processing volume 136. As a result, the pressure remains balanced enough to prevent the substrate support 106 from being misaligned. The overlap structure 180 reduces migration of the one or more process gases P1 toward the backside of the substrate support 106 and/or into the purge volume 138 while allowing pressure equalization between the purge volume 138 and the processing volume 136.

In one or more embodiments, the overlap structure 180 is formed of a quartz material. The quartz material of the overlap structure 180 provides a thermal shielding effect below the substrate support 106. For example, the overlap structure 180 can reduce radiative and/or convective thermal loss along an edge region of the substrate support 106. In some embodiments, the overlap structure 180 provides a greenhouse effect that maintains a more thermally uniform environment adjacent the edge region of the substrate support 106. In one or more embodiments, the overlap structure 180 is supported by the support surface 201 of each of the one or more arms 119. In one or more embodiments, the overlap structure 180 is welded to the one or more arms 119. In one or more embodiments, the overlap structure 180 is supported by the shaft 118.

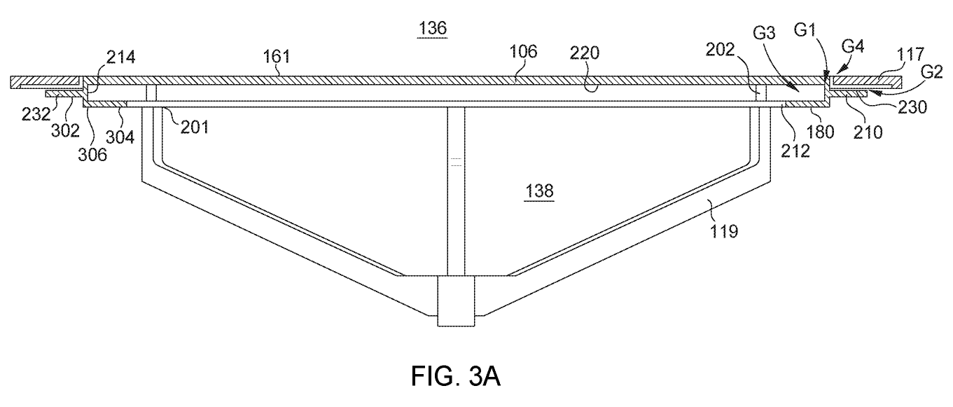

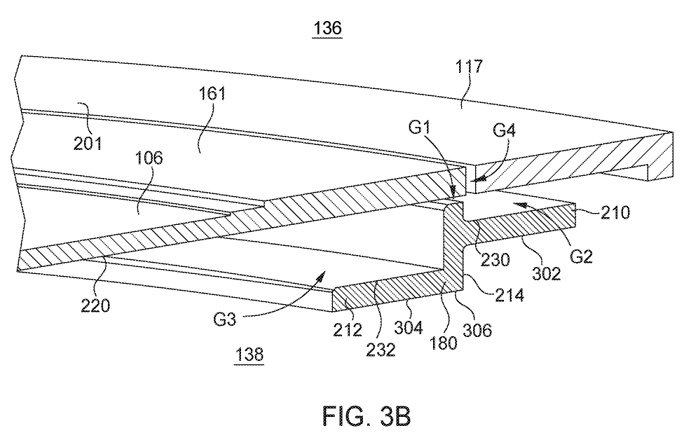

FIG. 3A is a schematic cross sectional view of the overlap structure 180, according to one or more embodiments. FIG. 3B is a schematic isometric view of the overlap structure 180, according to one or more embodiments. FIGS. 3A and 3B show the overlap structure 180 including the outer portion 210, the inner portion 212, and the protrusion feature 214. In one or more embodiments, the third gap G3 is greater than the second gap G2, as shown in FIGS. 3A and 3B. The protrusion feature 214 extends past the lower surface 302 of the outer portion 210. The lower surface 304 of the inner portion 212 is coplanar with the lower surface 306 of the protrusion feature 214. It is contemplated that the outer portion 210, the inner portion, the protrusion feature 214, or a combination thereof can include multiple arrangements.

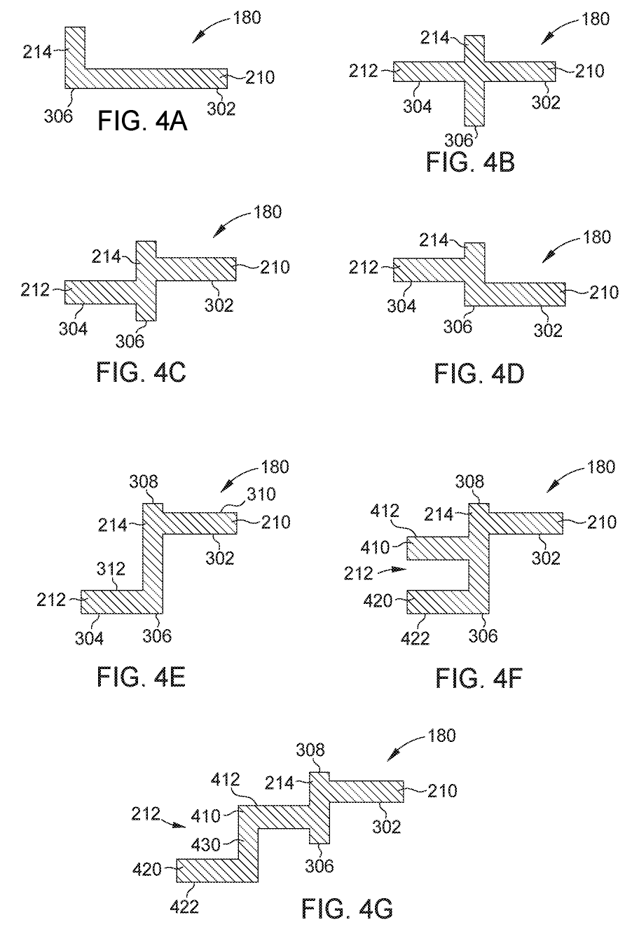

FIGS. 4A-4G are schematic cross sectional views of a portion of the overlap structure 180, according to one or more embodiments. FIG. 4A includes the outer portion 210 and the protrusion feature 214. In one or more embodiments, as shown in FIG. 4A, the overlap structure 180 does not include the inner portion 212. In one or more embodiments, the lower surface 302 of the outer portion is coplanar with the lower surface 306 of the protrusion feature 214. It is contemplated that in one or more embodiments, the lower surface 306 of the protrusion feature 214 extends past the lower surface 302 of the outer portion 210.

FIGS. 4B and 4C include the lower surface 306 of the protrusion feature 214 extending past the lower surface 302 of the outer portion 210 and the lower surface 304 of the inner portion 212. In one or more embodiments, as shown in FIG. 4B the lower surface 302 of the outer portion 210 and the lower surface 304 of the inner portion 212 are coplanar. In one or more embodiments, as shown in FIG. 4C the lower surface 302 of the outer portion 210 and the lower surface 304 of the inner portion 212 are misaligned from one another. In one or more embodiments, as shown in FIG. 4D, the lower surface 306 of the protrusion feature 214 extends past the lower surface 304 of the inner portion. The lower surface 302 of the outer portion 210 and the lower surface 306 of the protrusion feature 214 are coplanar. It should be understood that the embodiments described above are not meant to be limiting and that the overlap structure 180 may include any combination of the geometries described above.

FIG. 4E includes an upper surface 308 of the protrusion feature 214 extending past an upper surface 310 of the outer portion 210 and an upper surface 312 of the inner portion 212. In one or more embodiments, the upper surface 310 of the outer portion 210 and the upper surface 312 of the inner portion 212 are offset from one another.

In one or more embodiments, the inner portion 212 includes multiple sections. In FIG. 4F the inner portion 212 includes a first section 410 and a second section 420. In one or more embodiments, the upper surface 308 of the protrusion feature 214 extends past an upper surface 412 of the first section 410. In one or more embodiments, the lower surface 306 of the protrusion feature 214 and the lower surface 422 of the second section 420 are coplanar. In one or more embodiments, the lower surface 422 of the second section 420 and the upper surface 412 of the first section 410 are parallel to one another. In one or more embodiments, the second section 420 defines a central opening extending through the second section 420. In one or more embodiments, the second section 420 forms a plate, the plate not including a central opening.

In FIG. 4G the inner portion 212 includes a first section 410 and a second section 420 and a protrusion section 430. In one or more embodiments, the upper surface 308 of the protrusion feature 214 extends past an upper surface 412 of the first section 410. In one or more embodiments, the first section 410 and the second section 420 are parallel to the substrate support 106. In one or more embodiments, the second section 420 includes a central opening defining an inner dimension. The protrusion section 430 is between the first section 410 and the second section 420. The protrusion section 430 extends towards the lower surface 220 of the substrate support 106. In one or more embodiments the protrusion section 430 is perpendicular to the substrate support 106. In one or more embodiments, the second section 420 defines a central opening extending through the second section 420. In one or more embodiments, the second section 420 forms a plate, the plate not including a central opening.

Embodiments of the present disclosure include an overlap structure for use in a semiconductor processing chamber. The overlap structure increases a migration path length between a processing volume and a backside region of a substrate support, thereby reducing diffusion of process gas species toward the backside region of the substrate support. The overlap structure can also permit pressure equalization between the processing volume and a purge volume, while remaining tolerant or stable under dynamic pressure differentials between the purge volume and the processing volume. In one or more embodiments, the overlap structure also reduces thermal loss along an edge region of the substrate support and provides a more uniform thermal environment near support pin contact locations.

It is contemplated that one or more aspects disclosed herein may be combined. As an example, one or more aspects, features, components, operations and/or properties of processing chamber 100; the substrate 102; the upper body 156, the lower body 148; the flow module 112; the upper plate 108; the lower plate 110; the plurality of upper heat sources 141, the plurality of lower heat sources 143; the substrate support 106; the processing volume 136; the purge volume 138; the pre-heat ring 117; the one or more arms 119; the overlap structure 180; the outer portion 210; the inner portion; and/or the protrusion feature 214 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A processing chamber applicable for use in semiconductor manufacturing, comprising:
a chamber body at least partially defining a processing volume;
a substrate support disposed in the processing volume; and
a pre-heat ring disposed at least partially outwardly of the substrate support; and
an overlap structure disposed below the substrate support, at least a portion of the overlap structure extending below the pre-heat ring.

2. The processing chamber of claim 1, wherein the overlap structure is a ring.

3. The processing chamber of claim 1, wherein the overlap structure is a plate.

4. The processing chamber of claim 1, wherein the overlap structure and the substrate support are axially aligned with one another.

5. The processing chamber of claim 1, wherein the overlap structure comprises:
an inner portion;
an outer portion; and
a protrusion feature disposed between the inner portion and the outer portion.

6. The processing chamber of claim 5, wherein the protrusion feature is perpendicular to the substrate support.

7. The processing chamber of claim 5, further comprising:
a first gap defined by a distance between the protrusion feature of the overlap structure and a lower surface of the substrate support;
a second gap defined by a distance between an upper surface of the outer portion of the overlap structure and the lower surface of the substrate support;
a third gap defined by a distance between an upper surface of the inner portion of the overlap structure and the lower surface of the substrate support; and
a fourth gap defined by a distance between the pre-heat ring and the substrate support.

8. The processing chamber of claim 7, wherein the first gap is less than the second gap and the third gap.

9. The processing chamber of claim 7, wherein the second gap is from about 3mm to about 30mm.

10. The processing chamber of claim 7 wherein the overlap structure is formed of a quartz material.

11. An overlap structure for use in a semiconductor processing chamber comprising:
an inner portion;
an outer portion disposed outwardly of the inner portion, wherein the inner portion and the outer portion are parallel to one another;
a protrusion feature disposed between the inner portion and the outer portion, wherein the protrusion feature is perpendicular to the inner portion and the outer portion; and
one or more openings extending through the inner portion of the overlap structure.

12. The overlap structure of claim 11, wherein the overlap structure is a ring.

13. The overlap structure of claim 11, wherein the overlap structure is a plate.

14. The overlap structure of claim 11, wherein the overlap structure is formed of a quartz material.

15. The overlap structure of claim 11, wherein a lower surface of the protrusion feature is coplanar to a lower surface of the inner portion, and a lower surface of the outer portion.

16. The overlap structure of claim 11, wherein a lower surface of the protrusion feature extends past a lower surface of the inner portion and a lower surface of the outer portion.

17. The overlap structure of claim 11, wherein a lower surface of the inner portion and a lower surface of the outer portion are offset from one another.

18. A processing chamber applicable for use in semiconductor manufacturing, comprising:
a chamber body;
a plate, the chamber body and the plate at least partially defining a processing volume;
one or more heat sources configured to heat the processing volume;
a substrate support disposed in the processing volume;
a pre-heat ring disposed at least partially outwardly of the substrate support; and
an overlap structure disposed below the substrate support, at least a portion of the overlap structure extending below the pre-heat ring, the overlap structure comprising:
an inner portion;
an outer portion; and
a protrusion feature disposed between the inner portion and the outer portion, wherein the protrusion feature is perpendicular to the inner portion and the outer portion;
a first gap defined by a distance between the protrusion feature of the overlap structure and a lower surface of the substrate support;
a second gap defined by a distance between an upper surface of the outer portion of the overlap structure and the lower surface of the substrate support;
a third gap defined by a distance between an upper surface of the inner portion of the overlap structure and the lower surface of the substrate support; and
a fourth gap defined by a distance between the pre-heat ring and the substrate support.

19. The processing chamber of claim 18, wherein the overlap structure is a ring.

20. The processing chamber of claim 18, wherein the overlap structure is a plate.
